(19) United States
(12) Patent Application Publication
(10) Pub. No.: US 2024/0048076 A1
(43) Pub. Date: Feb. 8, 2024

(54) POWER GENERATION ELEMENT AND POWER GENERATION APPARATUS USING POWER GENERATION ELEMENT

(71) Applicant: CANON KABUSHIKI KAISHA, Tokyo (JP)

(72) Inventor: YUICHIRO MIYAUCHI, Kanagawa (JP)

(21) Appl. No.: 18/355,216

(22) Filed: Jul. 19, 2023

(30) Foreign Application Priority Data
Aug. 2, 2022 (JP) 2022-123184

(51) Int. Cl. H02N 2/18; H10N 35/80; H10N 35/00

(52) U.S. Cl. CPC H02N 2/186; H10N 35/80; H10N 35/101

(57) ABSTRACT

A power generation element includes a magnetostrictive plate, a coil enclosing at least a part of the magnetostrictive plate, a magnetic field generation portion that generates a magnetic field, a yoke including a ferromagnetic body, and a non-magnetic body. The magnetostrictive plate contains a magnetostrictive material and has one fixed end. The power generation element generates power when force is applied to the magnetostrictive plate. The yoke spans from one towards another partial area of the magnetostrictive plate. The one partial area of the magnetostrictive plate, the non-magnetic body, and one end of the yoke at the one partial area of the magnetostrictive plate are disposed in this order. Another end of the yoke faces the other partial area through a gap. The one partial area is on one surface of the magnetostrictive plate and the magnetic field generation portion is provided on another surface of the magnetostrictive plate.

### BACKGROUND

### Field

The disclosure of the present specification relates to a power generation element and a power generation apparatus using the power generation element.

### Description of the Related Art

In recent years, an “energy harvesting” technique that obtains power from unused energy existing in an environment has attracted attention as an energy saving technique. In particular, vibration power generation for obtaining power from vibration has been proposed to be applied to a power supply for constant communication Internet of Things (IoT), charging of a mobile device, and the like, because the vibration power generation is higher in energy density than thermoelectric power generation for obtaining power from heat. For example, a movable-magnet power generation method for vibrating a magnet by vibration in the environment to cause a coil to generate an induced electromotive force has been applied in various forms. Further, in recent years, power generation using an inverse magnetostrictive phenomenon (hereinafter, referred to as inverse magnetostrictive power generation) in which a magnetic flux density is changed due to change in force in place of vibration of a magnet has been proposed.

Japanese Patent Application Laid-Open No. 2021-136826 discusses an inverse magnetostrictive power generation element in which a magnetostrictive portion and a magnetic portion (yoke) are magnetically connected in parallel, as a configuration of the inverse magnetostrictive power generation element. Japanese Patent No. 6174053 discusses an inverse magnetostrictive power generation element in which a yoke and a magnetostrictive plate are not in contact with each other.

### SUMMARY

The present disclosure is directed towards reducing leakage of magnetic flux generated from the yoke such as in a case where a size of the power generation element is reduced so that the magnetic flux of a magnetic field generation portion is more likely to be efficiently used for power generation in some cases. Here, the present disclosure is directed to a power generation element that can improve power generation efficiency in power generation using a magnetostrictive material, and to a power generation apparatus using the power generation element.

According to an aspect of the present disclosure, a power generation element includes a magnetostrictive plate containing a magnetostrictive material and having one fixed end in a longitudinal direction of the magnetostrictive plate, a coil configured to enclose at least a part of the magnetostrictive plate, a magnetic field generation portion configured to generate a magnetic field, a yoke including a ferromagnetic body, and a non-magnetic body, wherein the power generation element generates power in response to application of force to the magnetostrictive plate, wherein the yoke is a bridge-like yoke bridged from a position corresponding to one partial area of the magnetostrictive plate toward a position corresponding to another partial area of the magnetostrictive plate, wherein the one partial area of the magnetostrictive plate, the non-magnetic body, and one end of the yoke at a position corresponding to the one partial area of the magnetostrictive plate are disposed in this order, wherein another end of the yoke faces the other partial area of the magnetostrictive plate through a gap, and wherein the one partial area is on one surface of the magnetostrictive plate and the magnetic field generation portion is provided on another surface of the magnetostrictive plate.

Further features of the present disclosure will become apparent from the following description of exemplary embodiments with reference to the attached drawings.

### BRIEF DESCRIPTION OF THE DRAWINGS

FIGS. 1A and 1B are schematic diagrams each illustrating an example of a configuration of a power generation element according to an exemplary embodiment.

FIGS. 2A and 2B are schematic diagrams each illustrating an example of a principle of the power generation element according to the exemplary embodiment.

FIGS. 3A to 3F are schematic diagrams illustrating an example of a method of manufacturing the power generation element according to the exemplary embodiment.

FIGS. 4A and 4B are schematic diagrams each illustrating an example of a configuration of a power generation element according to a first example.

FIGS. 5A to 5C are schematic diagrams each illustrating an example of a configuration of a power generation element according to a second example.

### DESCRIPTION OF THE EMBODIMENTS

Preferred exemplary embodiments of the present disclosure are described in detail with reference to accompanying drawings. The disclosure of the present specification is not limited to the following exemplary embodiments. Various modifications (including organic combinations of exemplary embodiments) can be made based on the spirit of the disclosure of the present specification, and are not excluded from the scope of the disclosure of the present specification. In other words, configurations obtained by combining the exemplary embodiments and modifications described below are all included in the exemplary embodiments disclosed in the present specification.

A power generation element according to a first exemplary embodiment is a power generation element that generates heat by using an inverse magnetostrictive phenomenon in which a magnetic flux density in a magnetostrictive plate is changed by change in stress applied to the magnetostrictive plate. In the present exemplary embodiment, the stress applied to the magnetostrictive plate is changed by vibration of a holding portion, application of force to a coupling plate, or the like. The power generation element according to the present exemplary embodiment improves power generation efficiency because a non-magnetic body having a function of inducing a leakage magnetic flux not contributing power generation into a coil is arranged in order of a magnet, a magnetostrictive plate, the non-magnetic body, and a yoke. In other words, the power generation element according to the present exemplary embodiment includes the magnetostrictive plate, the non-magnetic body, and the yoke in this order, and includes the magnet serving as a magnetic field adjustment portion on the other surface of the magnetostrictive plate. The configuration of the power generation element according to the present exemplary embodiment is to be described in detail below.

### Configuration of Power Generation Element

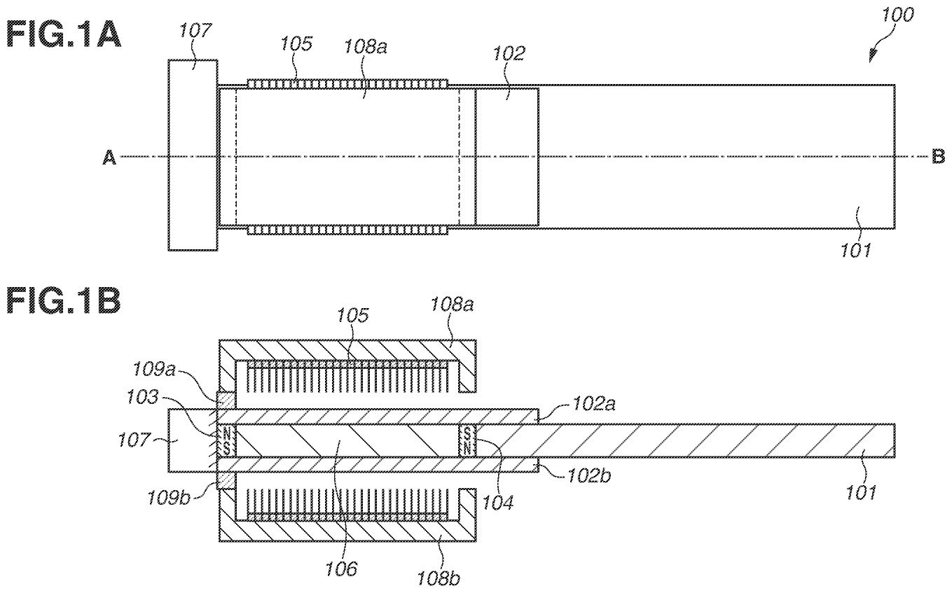

The configuration of the power generation element according to the present exemplary embodiment is to be described with reference to FIGS. 1A and 1B. FIG. 1A is a schematic top view illustrating the configuration of the power generation element according to the present exemplary embodiment, and FIG. 1B is a schematic cross-sectional view taken along line A-B in FIG. 1A, and illustrating the configuration of the power generation element according to the present exemplary embodiment.

A power generation element 100 according to the present exemplary embodiment is fixed with a fixing portion 107, and includes a coupling plate 101, a magnetostrictive portion 102 containing a magnetostrictive material and including a magnetostrictive plate 102a and a magnetostrictive plate 102b, a magnetic field generation portion including a magnet 103 serving as a first magnetic field generation area and a magnet 104 serving as a second magnetic field generation area, a coil 105, a non-magnetic area 106, a yoke 108 including a yoke 108a and a yoke 108b, and a non-magnetic portion 109 including a non-magnetic body 109a and a non-magnetic body 109b. More specifically, the power generation element 100 according to the present exemplary embodiment includes the magnetostrictive portion 102 containing a magnetostrictive material and having one fixed end in a longitudinal direction, the coil 105 enclosing at least a part of the magnetostrictive portion 102, and the magnetic field generation portion for generating a magnetic field, and generates power in response to application of force to the magnetostrictive portion. The power generation element 100 further includes the yoke 108 including a ferromagnetic body, and the non-magnetic portion 109. The yoke 108 is a bridge-like yoke bridged from a position corresponding to a partial area on one surface of the magnetostrictive portion 102 to span toward a position corresponding to the other partial area of the magnetostrictive portion 102. The partial area of the magnetostrictive portion 102, the non-magnetic portion 109, and one end part of the yoke 108 at a position corresponding to the partial area of the magnetostrictive portion 102 are disposed in this order. The other end part of the yoke 108 faces the other partial area of the magnetostrictive portion 102 through a gap. The magnetic field generation portion is provided on the other surface of the magnetostrictive portion 102. The components of the power generation element 100 according to the present exemplary embodiment are to be described below. In an example, the power generation element 100 is configured to be responsive to magnetostriction in that material of the power generation element 100 is configured to be reversibly deformed, change shape, and/or change dimensions when a vector field such as a magnetic field is applied.

The coupling plate 101 has one end fixed to the magnetostrictive portion 102, and vibrates by receiving external force such as compression stress and tensile stress. A method of coupling the coupling plate 101 is not particularly limited as long as the magnetostrictive portion 102 and the coupling plate 101 are firmly fixed. For example, laser welding, bonding with an adhesive, solder joining, ultrasonic joining, or fixing with a bolt and a nut can be used. The external force such as the compression stress and the tensile stress is continuously applied to the coupling plate 101. For this reason, the coupling plate 101 is preferably made of a material having ductility. Further, the material of the coupling plate 101 is selected based on a configuration of a magnetic circuit with the magnetostrictive portion 102. Accordingly, in a case where the coupling plate 101 is used as a constituent element of the magnetic circuit, a magnetic material such as carbon steel, terrific stainless steel (e.g., SUS430), and martensitic stainless steel (e.g., SUS420J2) is used. In contrast, in a case where the coupling plate 101 is not used as the constituent element of the magnetic circuit, a non-magnetic material such as austenitic stainless steel (e.g., SUS304, SUS303, or SUS316) is used.

The force is applied to the coupling plate 101 such that the coupling plate 101 vibrates in a vertical direction in FIG. 1B. For this reason, a spring member may be used as the coupling plate 101 so as to reduce mechanical attenuation of the vibration. The force inducing the vibration in the vertical direction in FIG. 1B can be generated by, for example, application of ground excitation caused by fixing of the fixing portion 107 to a vibration source vertically vibrating, or by operation in which force is applied to a front end of the coupling plate 101 on a side opposite to a connection portion of the coupling plate 101 and the front end is flipped. The above-described force application methods are merely examples, and the other methods applying the force to the magnetostrictive portion 102 can be used. Further, the above-described materials used for the coupling plate 101 are examples, and the material of the coupling plate 101 is not limited to the examples.

Each of the magnetostrictive plate 102a and the magnetostrictive plate 102b included in the magnetostrictive portion 102 is a member containing a magnetostrictive material. Compression stress and tensile stress are continuously applied to the magnetostrictive portion 102. For this reason, the magnetostrictive portion 102 preferably contains a magnetostrictive material having ductility. Although a type of the magnetostrictive material is not particularly limited, a well-known magnetostrictive material such as an iron-gallium alloy, an iron-cobalt alloy, an iron-aluminum alloy, an iron-gallium-aluminum alloy, and an iron-silicon-boron alloy is preferably used. A shape of the magnetostrictive portion 102 is not particularly limited as long as the magnetostrictive portion 102 can be coupled with the coupling plate 101. A rectangular parallelepiped shape, a columnar shape, or the like is preferably used.

Each of the yokes 108a and 108b is a bridge-like yoke bridged from the position corresponding to the partial area on one surface of the magnetostrictive portion 102 toward the position corresponding to the other partial area of the magnetostrictive portion 102. The yokes 108a and 108b are magnetically connected to the magnetostrictive plates 102a and 102b, respectively, through the non-magnetic portion 109. Although a material of the yokes is not particularly limited, each of carbon steel, terrific stainless steel (e.g., SUS430), or martensitic stainless steel (e.g., SUS420J2) is used as a material of each of the yokes 108a and 108b. The magnetostrictive portion 102 and the non-magnetic portion 109 are coupled with each other. A coupling method is not particularly limited as long as the magnetostrictive portion 102 and the non-magnetic portion 109 are firmly fixed. For example, laser welding, bonding with an adhesive, solder joining, ultrasonic joining, or fixing with a bolt and a nut can be used.

The magnet 103 serving as the first magnetic field generation area and the magnet 104 serving as the second magnetic field generation area, which are included in the magnetic field generation portion, are attached to magnetize the magnetostrictive plate 102a and the magnetostrictive plate 102b in opposite directions. Although the magnet 103 and the magnet 104 are not particularly limited, a neodymium magnet, a samarium-cobalt magnet, or the like is used for each of the magnet 103 and the magnet 104 included in the magnetic field generation portion.

Although directions of magnetic poles of the magnets 103 and 104 are not particularly limited, directions of magnetic poles of the magnets 103 and 104 included in the magnetic field generation portion are opposite to each other in the vertical direction as illustrated in the schematic cross-sectional view in FIG. 1B. However, the directions of the magnetic poles of the magnets 103 and 104 in the schematic cross-sectional view in FIG. 1B are merely an example, and N poles and S poles may be inverted from those illustrated in FIG. 1B. In other words, it is sufficient that a magnetic pole surface of the magnet 103 and a magnetic pole surface of the magnet 104 different from each other are fixed to the magnetostrictive portion 102.

The arrangement of the magnet 103 serving as the first magnetic field generation area and the magnet 104 serving as the second magnetic field generation area, which are included in the magnetic field generation portion, is not particularly limited to the above-described arrangement as long as the magnetostrictive plate 102a and the magnetostrictive plate 102b are magnetized in opposite directions. Although the magnets 103 and 104 are not particularly limited, a neodymium magnet, a samarium-cobalt magnet, or the like is used for each of the magnets 103 and 104.

The coil 105 is disposed so as to enclose at least a part of each of the magnetostrictive plate 102a and the magnetostrictive plate 102b, and generates a voltage based on temporal change of the magnetic fluxes generated by the magnetostrictive plate 102a and the magnetostrictive plate 102b, according to the law of electromagnetic induction. This makes it possible to increase the number of turns of the coil 105 irrespective of a distance between the two magnetostrictive plates. Although a material of the coil 105 is not particularly limited, a copper wire is preferably used as a material of the coil 105.

Although a material of the non-magnetic area 106 is not particularly limited, gas or solid is used as a material of the non-magnetic area 106. Air, a non-magnetic metal having ductility, or austenitic stainless steel (e.g., SUS304, SUS303, or SUS316) is preferably used. The non-magnetic area 106 may be integrated with the coupling plate 101.

In a case where the power generation element 100 is enclosed in a container integrated with the fixing portion 107, it is possible to reduce a risk of damaging the power generation element 100, a risk of the power generation element 100 to come into contact with the other members inhibiting vibration, and the like. Although a material of the container is not particularly limited, using a magnetic material such as carbon steel, ferritic stainless steel (e.g., SUS430), and martensitic stainless steel (e.g., SUS420J2) makes it possible to achieve an effect of a magnetic shield, and to reduce influence of external magnetism.

It is sufficient for the non-magnetic portion 109 to be connected to one end of the bridge-like yoke 108 and a part of the surface of the magnetostrictive plate, and the surface of the magnetostrictive plate is a surface on a side opposite to the surface provided with the magnetic field generation portion. Although a material of the non-magnetic portion 109 is not particularly limited, for example, a non-magnetic metal having ductility or austenitic stainless steel (e.g., SUS304, SUS303, or SUS316) is used as a material of the non-magnetic portion 109. A method for coupling with the magnetostrictive portion 102 and the yoke 108 is not particularly limited as long as the non-magnetic portion 109 is firmly fixed to the magnetostrictive portion 102 and the yoke 108. For example, laser welding, bonding with an adhesive, solder joining, ultrasonic joining, or fixing with a bolt and a nut can be used.

In other words, the power generation element 100 according to the present exemplary embodiment includes the magnetostrictive plate containing the magnetostrictive material and having the fixed end in the longitudinal direction, the coil for enclosing at least a part of the magnetostrictive plate, and the magnetic field generation portion for generating the magnetic field, and generates power in response to application of force to the magnetostrictive plate. The power generation element further includes the yoke including the ferromagnetic body, and the non-magnetic body. The yoke is the bridge-like yoke bridged from the position corresponding to the partial area on one surface of the magnetostrictive plate toward the position corresponding to the other partial area of the magnetostrictive plate. The partial area of the magnetostrictive plate, the non-magnetic body, and one end part of the yoke at the position corresponding to the partial area of the magnetostrictive plate are disposed in this order. The other end part of the yoke faces the other partial area of the magnetostrictive plate through the gap. The magnetic field generation portion is provided on the other surface of the magnetostrictive plate.

### Action

The power generation element 100 according to the present exemplary embodiment is a kind of an electromagnetic induction power generation element that converts change in magnetic flux into a voltage by a coil. In the electromagnetic induction, electromotive force V is generated based on the following expression (1).

V=N×ΔΦ/Δt (1)

In the expression (1), N is the number of turns of the coil 105, Δt is an extremely short time, and ΔΦ is a change amount of magnetic flux in the coil 105 in the time Δt. In the power generation based on the inverse magnetostrictive phenomenon, the change amount of magnetic flux ΔΦ is generated by change in a curve indicating relationship between a magnetic field H and a magnetic flux density B (hereinafter, BH curve), caused by change in stress applied to the magnetostrictive material. The change amount of magnetic flux ΔΦ becomes excessively small in a case where the application magnetic field H is excessively large or excessively small. For this reason, it is necessary to apply an appropriate magnetic field to the magnetostrictive material. However, in a case where the size of the entire power generation element is small, leakage magnetic flux is generated from the yoke because the distance between the yoke and the magnet is small. As a result, an area where the magnetic flux density is insufficient may be generated in the magnetostrictive plate. The present exemplary embodiment discusses the power generation element that is improved in power generation efficiency by reducing the leakage magnetic flux from the yoke and inducing the reduced magnetic flux to the magnetostrictive plate.

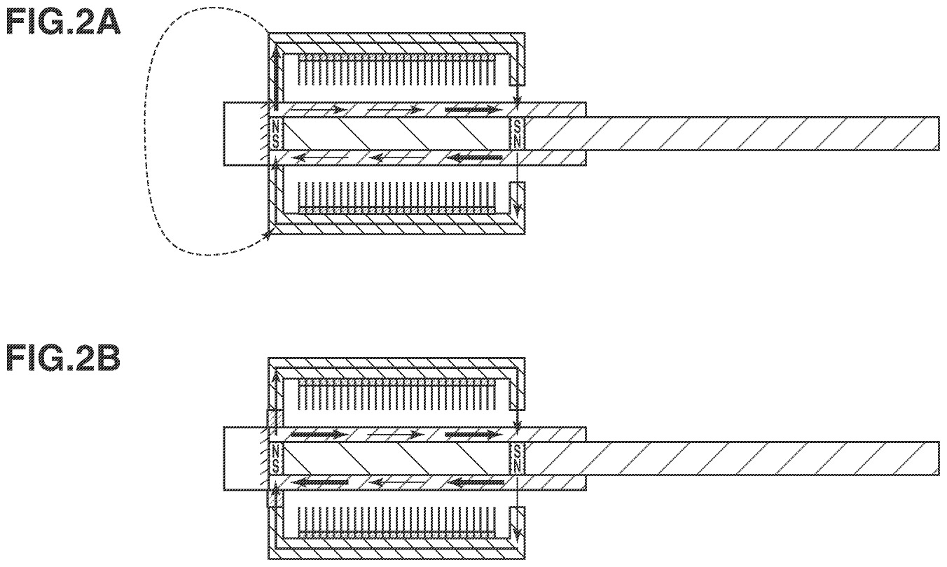

FIG. 2A is a schematic cross-sectional view schematically illustrating, by an arrow and a thickness thereof, a direction and a magnitude of magnetic flux density passing through a magnetostrictive plate of a power generation element for generating power by the inverse magnetostrictive phenomenon. FIG. 2B is a schematic cross-sectional view schematically illustrating, by an arrow and a thickness thereof, a direction and a magnitude of the magnetic flux density of the power generation element 100 illustrated in FIGS. 1A and 1B as an example of the present exemplary embodiment.

FIG. 2A illustrates a state where the magnetic flux leaks to outside of the power generation element 100 at the yoke near the magnet 103, in particular, at a corner part of the bridge-like yoke and the like. A dotted line schematically illustrates the magnetic flux leaking to outside of the yoke. As illustrated in FIG. 2A, in a case where the magnetic flux leaks, the magnetic flux density passing in a direction perpendicular to the cross-section inside the coil is reduced. In a case where the magnetic flux density is reduced near the magnet 103 as compared with the magnetic flux density near the magnet 104, distribution occurs in the magnetic flux density in the magnetostrictive portion 102, and power generation efficiency is deteriorated. As a result of keen examination, it is found that providing the non-magnetic portion 109 between the one end of the bridge-like yoke 108 and a part of the surface of the magnetostrictive portion 102 as illustrated in FIG. 2B makes it possible to suppress the leakage magnetic flux of the yoke as illustrated by the dotted line in FIG. 2A, the magnetic flux density of the magnetostrictive portion 102 near the magnet 103 can be increased, and the power generation efficiency can be improved.

The non-magnetic portion 109 is provided between the end part of the yoke 108 and one surface of the magnetostrictive portion 102, and the magnet is provided on a surface opposite to the one surface of the magnetostrictive portion 102. The leakage magnetic flux is the most in the magnetization direction near the magnet. Accordingly, providing the non-magnetic portion 109 in the magnetization direction makes it possible to adjust a magnetic resistance, and further providing the end part of the yoke 108 in the magnetization direction makes it possible to reduce the leakage magnetic flux.

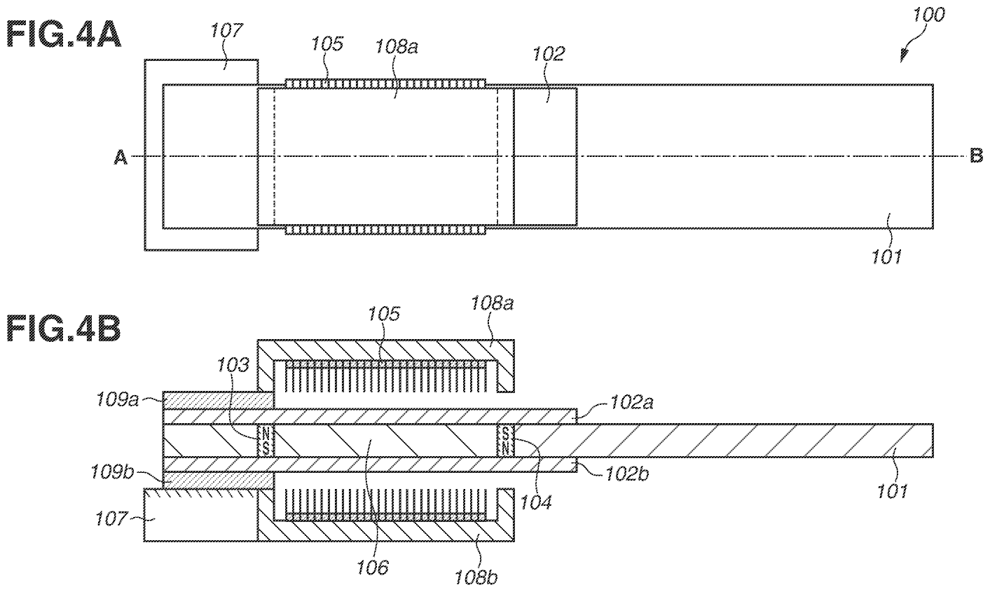

As illustrated in FIGS. 4A and 4B, the non-magnetic portion 109 may be in contact with a part or the whole of the end part of the bridge-like yoke.

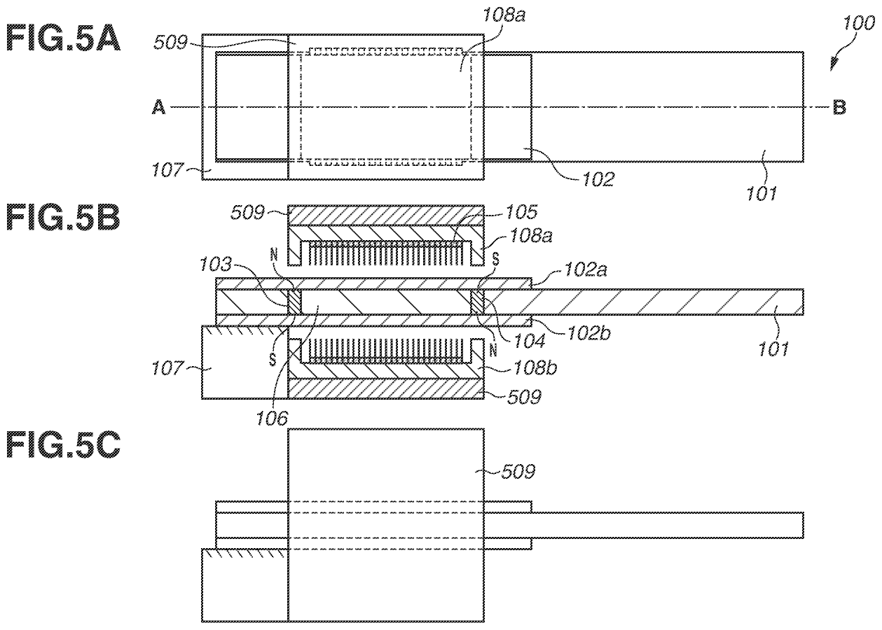

It is found that even in a case where the magnetostrictive portion 102 is not in contact with both ends of the bridge-like yoke 108 as illustrated in FIGS. 5A to 5C unlike FIGS. 1A and 1B, it is possible to reduce the leakage magnetic flux of the yoke 108 and to improve power generation efficiency. In the case of the configuration, the leakage magnetic flux is the most in the magnetization direction near the magnet. Accordingly, a gap as a non-contact area is provided between the end part of the yoke 108 and the magnetostrictive portion 102 in the magnetization direction, and the end part of the yoke 108 is provided in the magnetization direction, which makes it possible to reduce the leakage magnetic flux. FIG. 5B is a schematic cross-sectional view taken along line A-B in FIG. 5A, and FIG. 5C is a diagram as viewed from a direction perpendicular to the direction in FIG. 5A.

In other words, the power generation element 100 according to the present exemplary embodiment includes the magnetostrictive portion 102 containing the magnetostrictive material and having the fixed end in the longitudinal direction, the coil 105 for enclosing at least a part of the magnetostrictive portion 102, and the magnetic field generation portion for generating the magnetic field, and generates power in response to application of force to the magnetostrictive portion 102. The power generation element 100 further includes the yoke 108 including the ferromagnetic body, the fixing portion 107 of the yoke 108, and the non-magnetic body. The position of the yoke 108 is fixed to a part of the magnetostrictive portion 102 through the fixing portion 107. The yoke 108 is the bridge-like yoke bridged from the position corresponding to the partial area on one surface of the magnetostrictive portion 102 toward the position corresponding to the other partial area of the magnetostrictive portion 102. Both ends of the yoke 108 face the one surface of the magnetostrictive portion 102 through the gap. The magnetic field generation portion is provided on the other surface of the magnetostrictive portion 102.

The present exemplary embodiment is to be described in detail by using specific examples. The present exemplary embodiment is not limited to configurations and forms of the following examples.

### Method of Manufacturing Power Generation Element

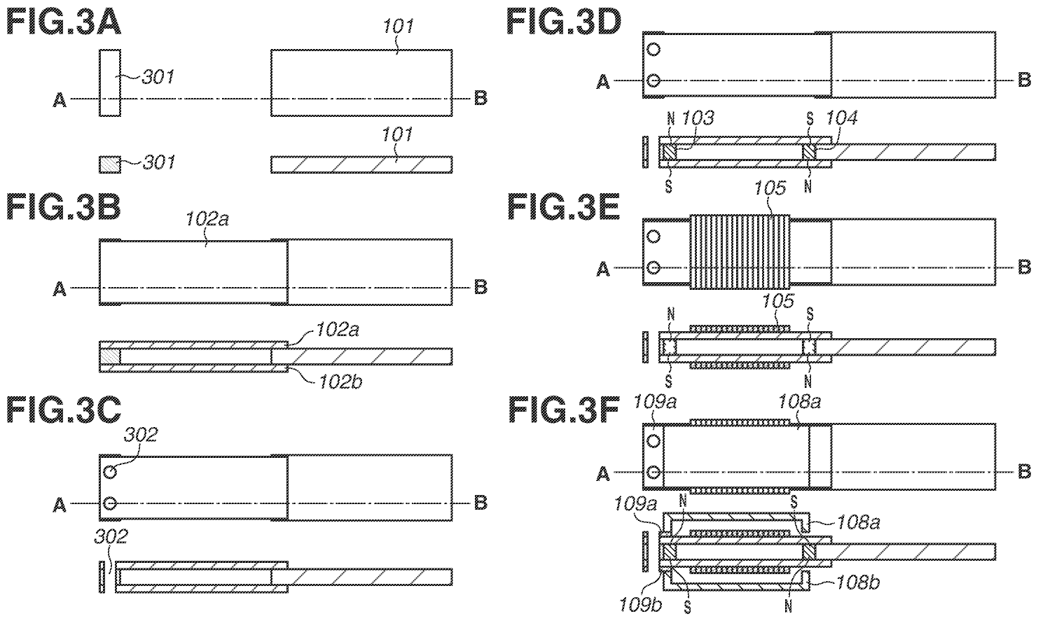

In a first example, the power generation element 100 illustrated in FIGS. 4A and 4B was fabricated. Examples of manufacturing steps are to be described below with reference to FIGS. 3A to 3F.

An upper diagram in each of FIGS. 3A to 3F is a schematic top view, and a lower diagram is a schematic cross-sectional view taken along line A-B illustrated in the schematic top view.

First, as the coupling plate 101, a plate that was made of SUS304-CSP as austenitic stainless steel for a spring and had a thickness of 1.0 mm, a width of 16 mm, and a length of 35 mm was used. As a fixing plate 301, a plate that was made of SUS304 and had a thickness of 1.0 mm, a width of 16 mm, and a length of 5 mm was used. A reason for use of the austenitic stainless steel was because the austenitic stainless steel was a non-magnetic metal and reduced magnetic flux leakage between the magnetostrictive plate 102a and the magnetostrictive plate 102b. A reason for use of the spring material was because it was revealed as a result of examination that mechanical attenuation of the power generation element relating to power generation performance was small as compared with a case where a normal stainless material was used as illustrated in FIG. 3A.

Next, the magnetostrictive plates 102a and 102b were bonded to the coupling plate 101 and the fixing plate 301 with an epoxy adhesive. Thereafter, of the ridge lines of the magnetostrictive plates 102a and 102b, joining is performed by performing laser welding on ridge lines in contact with the coupling plate 101 and the fixing plate 301.

Each of the magnetostrictive plates 102a and 102b used at this time was made of an iron-gallium alloy and had a thickness of 0.5 mm, a width of 15 mm, and a length of 25 mm as illustrated in FIG. 3B.

Subsequently, fixing screw holes 302 to fix the power generation element by a bolt or the like were fabricated in the magnetostrictive plates 102a and 102b and the coupling plate 101. The screw holes 302 enabled installation of the power generation element at various places. In power generation amount evaluation in the present example, a spacer having screw holes was installed on an optical surface plate, and the power generation element was fixed to the spacer by bolts through the fixing screw holes 302 as illustrated in FIG. 3C.

Next, a neodymium magnet having a thickness of 1.0 mm, a width of 12 mm, and a length of 2.0 mm was used as the magnet 103, and a neodymium magnet having a thickness of 1.0 mm, a width of 12 mm, and a length of 1.0 mm was used as the magnet 104. The magnet 103 and the magnet 104 were inserted such that directions of magnetic poles were opposite to each other as illustrated in FIG. 3D. After the magnet 103 and the magnet 104 were inserted, the magnet 103 and the magnet 104 were bonded and fixed between the magnetostrictive plate 102a and the magnetostrictive plate 102b with an epoxy adhesive as illustrated in FIG. 3D.

Next, as the coil 105, an air-core coil in which a copper wire having a wire diameter of 0.1 mm was turned 2000 times was inserted into an area between the magnet 103 and the magnet 104 so as to enclose the magnetostrictive plate 102a and the magnetostrictive plate 102b, and was fixed with electric insulation varnish as illustrated in FIG. 3E.

Finally, the non-magnetic portion 109 and the yoke 108 each including fixing screw holes were bonded with an epoxy adhesive, and the non-magnetic portion 109 and the yoke 108 were joined to each other by performing laser welding on ridge lines where the non-magnetic portion 109 and the yoke 108 were in contact with each other. Thereafter, the non-magnetic portion 109 and the yoke 108 were fixed through the screw holes 302. At this time, SUS304 was used as the non-magnetic portion 109, and a cold-rolled steel plate SPCC was used as the yoke 108 as illustrated in FIG. 3F.

### Evaluation of Power Generation Element

Power generation performance of the power generation element fabricated in the above-described manner was evaluated by vibrating the fixing portion by a vibrator and measuring an open voltage generated in the coil 105 by an oscilloscope. A frequency generated by the vibrator was set to 100 Hz, and a vibration acceleration was set to 1 G. A spindle having a natural frequency of 100 Hz was installed at a front end of a power generator. As a quantitative index of the power generation performance, a power generation amount P calculated by the following expression (2) from a voltage waveform measured by the oscilloscope was used.

P=Σ(V(t))²/(4×R)×Δt/t (2)

In the expression (2), V(t) was the open voltage at a time t measured by the oscilloscope, R was an electric resistance of the coil, Δt was temporal resolution of the oscilloscope, and Σ was summation with the time t. In the expression of the power generation amount P, an effect by an inductance of the coil was eliminated. This is because a coil having similar dimensions was used in the present example and a comparative example, and relative comparison was accordingly possible. As a result of the measurement and the evaluation by the above-described method, the electric resistance of the coil was 180 Ω, the maximum value of the open voltage was 7.9 V, and the power generation amount P was 19 mW from the expression (2).

In a second example, the power generation element 100 illustrated in FIGS. 5A to 5C was fabricated. It was found that, even in a case where a gap is provided and the magnetostrictive portion 102 is not in contact with both of the ends of the bridge-like yoke 108 as in the present example, it is possible to reduce the leakage magnetic flux of the yoke 108 and to improve power generation efficiency. In other words, one of the ends of the bridge-like yoke 108 was provided in the magnetization direction of the magnet, and the magnetostrictive plate and the yoke 108 were not in contact with each other.

The manufacturing method illustrated in FIGS. 3A to 3E was similar to the manufacturing method in the first embodiment. In FIG. 3F, the yoke 108 connected to a case 509 illustrated in FIGS. 5A to 5C was prepared, and was fixed to the fixing portion by screws through the screw holes 302, thereby manufacturing the power generation element 100. The fixing portion was a spacer that was made of SUS304 and was fixed to an optical surface plate through the screw holes. The case 509 was fixed by being partially integrated with the spacer. A material of the case 509 is not particularly limited to the example as the material was a non-magnetic body. In this example, austenitic stainless steel (SUS304) was used.

### Evaluation of Power Generation Element

Power generation performance of the power generation element fabricated in the above-described manner was evaluated in a manner similar to the first example. As a result of the evaluation, the electric resistance of the coil was 180 Ω, the maximum value of the open voltage was 8.0 V, and the power generation amount P was 20 mW.

In a first comparative example, unlike the power generation element in the first example illustrated in FIGS. 4A and 4B, a power generation element including magnetic plates in place of the non-magnetic bodies 109a and 109b was fabricated. Configurations including dimensions were the same as the configurations in FIGS. 4A and 4B, except that no magnetic field adjustment plate is provided. The power generation element was fabricated by replacing the non-magnetic plates with the magnetic plates in FIG. 3F.

### Evaluation of Power Generation Element

Power generation performance of the power generation element fabricated in the above-described manner was evaluated in a manner similar to the first example. As a result of the evaluation, the electric resistance of the coil was 180 Ω, the maximum value of the open voltage was 6.5 V, and the power generation amount P was 13 mW.

Although the exemplary embodiments and the examples of the present disclosure are specifically described, the present disclosure is not limited to the above-described exemplary embodiments. The present disclosure can be variously modified based on the technical idea. For example, the numerical values and the components described in the above-described exemplary embodiments are merely examples. Different numerical values and different components may be used, as necessary.

### INDUSTRIAL APPLICABILITY

When the power generation element according to any of the above-described exemplary embodiments and examples is used, the power generation amount greater than the power generation amount by the existing inverse magnetostrictive power generation element can be obtained. This makes it possible to downsize the power generator (power generation apparatus). For this reason, this is particularly effective as the power generator for an apparatus having a size difficult to be installed so far. For example, the power generator can be used for a mobile device and the like. When the power generator is installed in a power generation apparatus including a mechanism vibrating the power generation element by ground excitation, for example, an industrial apparatus generating vibration, an office apparatus, a medical apparatus, or a housing of an automobile, a railroad vehicle, an airplane, a heavy machine, a vessel, or the like, the power generator can be expected to be used as a power supply of various kinds of apparatuses including an Internet of Things (IoT) apparatus. The housing may be a ferromagnetic body. Because the present disclosure can improve performance of the power generator, the present disclosure can be applied to various fields in addition to the above-described fields.

Embodiments of the present disclosure can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described Embodiments and/or that includes one or more circuits (e.g., application specific integrated circuit (ASIC)) for performing the functions of one or more of the above-described Embodiments, and by a method performed by the computer of the system or apparatus by, for example, reading out and executing the computer executable instructions from the storage medium to perform the functions of one or more of the above-described Embodiments and/or controlling the one or more circuits to perform the functions of one or more of the above-described Embodiments. The computer may include one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read-only memory (ROM), a storage of distributed computing systems, an optical disk (such as a compact disc (CD), digital versatile disc (DVD), or Blu-ray Disc™ (BD)), a flash memory device, a memory card, and the like.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2022-123184, filed Aug. 2, 2022, which is hereby incorporated by reference herein in its entirety.

What is claimed is:

1. A power generation element comprising:
a magnetostrictive plate containing a magnetostrictive material and having one fixed end in a longitudinal direction of the magnetostrictive plate;
a coil configured to enclose at least a part of the magnetostrictive plate;
a magnetic field generation portion configured to generate a magnetic field;
a yoke including a ferromagnetic body; and
a non-magnetic body,
wherein the power generation element generates power in response to application of force to the magnetostrictive plate,
wherein the yoke is a bridge-like yoke bridged from a position corresponding to one partial area of the magnetostrictive plate toward a position corresponding to another partial area of the magnetostrictive plate,
wherein the one partial area of the magnetostrictive plate, the non-magnetic body, and one end of the yoke at a position corresponding to the one partial area of the magnetostrictive plate are disposed in this order,
wherein another end of the yoke faces the other partial area of the magnetostrictive plate through a gap, and
wherein the one partial area is on one surface of the magnetostrictive plate and the magnetic field generation portion is provided on another surface of the magnetostrictive plate.

2. The power generation element according to claim 1, wherein the non-magnetic body is in contact with a part of the one partial area of the magnetostrictive plate.

3. The power generation element according to claim 1, wherein the non-magnetic body is fixed to a fixing portion to which the one fixed end of the magnetostrictive plate is fixed.

4. The power generation element according to claim 1, further comprising a fixing plate having one end fixed to the magnetostrictive plate and configured to vibrate by receiving external force.

5. A power generation apparatus comprising:
the power generation element according to claim 1; and
a mechanism configured to apply force to the power generation element.

6. A power generation apparatus comprising:
the power generation element according to claim 1; and
a mechanism configured to vibrate the power generation element by ground excitation.

7. A power generation apparatus comprising:
the power generation element according to claim 1; and
a housing configured to house the power generation element.

8. The power generation apparatus according to claim 7, wherein the housing is a housing ferromagnetic body.

9. A power generation element comprising:
a magnetostrictive plate containing a magnetostrictive material and having one fixed end in a longitudinal direction of the magnetostrictive plate;
a coil configured to enclose at least a part of the magnetostrictive plate;
a magnetic field generation portion configured to generate a magnetic field;
a yoke including a ferromagnetic body;
a fixing portion of the yoke; and
a non-magnetic body,
wherein the power generation element generates power in response to application of force to the magnetostrictive plate,
wherein a position of the yoke is fixed to a part of the magnetostrictive plate through the fixing portion,
wherein the yoke is a bridge-like yoke bridged from a position corresponding to one partial area of the magnetostrictive plate toward a position corresponding to another partial area of the magnetostrictive plate,
wherein both ends of the yoke face the one surface of the magnetostrictive plate through a gap, and
wherein the one partial area is on one surface of the magnetostrictive plate and the magnetic field generation portion is provided on another surface of the magnetostrictive plate.

10. The power generation element according to claim 9, wherein the yoke is fixed to the non-magnetic body.

11. The power generation element according to claim 9, further comprising a fixing plate having one end fixed to the magnetostrictive plate and configured to vibrate by receiving external force.

12. A power generation apparatus, comprising:
the power generation element according to claim 9; and
a mechanism configured to apply force to the power generation element.

13. A power generation apparatus comprising:
the power generation element according to claim 9; and
a mechanism configured to vibrate the power generation element by ground excitation.

14. A power generation apparatus comprising:
the power generation element according to claim 9; and
a housing configured to house the power generation element.

15. The power generation apparatus according to claim 14, wherein the housing is a housing ferromagnetic body.
